(19) United States
(12) Patent Application Publication
(10) Pub. No.: US 2026/0190570 A1
(43) Pub. Date: Jul. 2, 2026

(54) Display Substrate and Display Apparatus

(71) Applicants: BOE MLED Technology Co., Ltd., Beijing (CN); BOE Technology Group Co., Ltd., Beijing (CN)

(72) Inventors: Chenkai LIU, Beijing (CN); Ruoyu MA, Beijing (CN); Qian ZHANG, Beijing (CN); Xuehai QIAN, Beijing (CN); Baoxin ZHANG, Beijing (CN); Ping LI, Beijing (CN); Yushu GAN, Beijing (CN); Shaofei GUO, Beijing (CN); Liangliang JIN, Beijing (CN); Yueqiao LI, Beijing (CN); Xiaozhou LIU, Beijing (CN); Chen YANG, Beijing (CN); Bo GAO, Beijing (CN); Meiling JIN, Beijing (CN); Tao YANG, Beijing (CN); Xin JING, Beijing (CN)

(21) Appl. No.: 18/844,988

(22) PCT Filed: Oct. 10, 2023
(86) PCT No.: PCT/CN2023/123729

§ 371 Date: Sep. 9, 2024

(51) Int. Cl. H10H 29/49

(52) U.S. Cl. CPC H10H 29/49

(57) ABSTRACT

Disclosed are a display substrate and display apparatus. The display substrate includes a base substrate and multiple element groups (Z1), first-type signal lines and first-type connection lines on the base substrate. On a plane parallel to the display substrate, the multiple element groups are arranged in an array, the multiple first-type signal lines extend along a column direction and are arranged at intervals along a row direction intersecting the column direction, the multiple first-type connection lines extend along the row direction and are arranged at intervals along the column direction; in a direction perpendicular to a plane where the display substrate is located, first-type signal line and first-type connection line are in different conductive layers; the first-type signal line is electrically connected to at least two non-adjacent first-type connection lines, the first-type connection line is electrically connected to at least some of element groups in one row of element groups.

### CROSS-REFERENCE TO RELATED APPLICATION

The present application is a U.S. National Phase Entry of International Application No. PCT/CN2023/123729 having an international filing date of Oct. 10, 2023, the content of which is hereby incorporated by reference.

### TECHNICAL FIELD

The present disclosure relates to, but is not limited to, the field of display technologies, in particular to a display substrate and a display apparatus.

### BACKGROUND

Transparent display technology has a broad application prospect as it can present not only images in a display screen but also physical objects behind the display screen. The transparent display technology has been widely applied in display windows, transparent TV, vehicle-mounted technology, virtual reality (VR), augmented reality (AR) and other fields.

### SUMMARY

The following is a summary of subject matters described herein in detail. This summary is not intended to limit the protection scope of claims.

Embodiments of the present disclosure provide a display substrate and a display apparatus.

In a first aspect, an embodiment of the present disclosure provides a display substrate, including: a base substrate, a plurality of element groups, a plurality of first-type signal lines and a plurality of first-type connection lines disposed on the base substrate, on a plane parallel to the display substrate, the plurality of element groups are arranged in an array, the plurality of first-type signal lines extend along a column direction and are arranged at intervals along a row direction, the plurality of first-type connection lines extend along the row direction and are arranged at intervals along the column direction, the row direction intersects the column direction; in a direction perpendicular to a plane where the display substrate is located, a first-type signal line and a first-type connection line are located in different conductive layers.

Herein the first-type signal line is electrically connected to at least two non-adjacent first-type connection lines, and the first-type connection line is electrically connected to at least some of element groups in one of rows of element groups.

In some exemplary implementations, the plurality of first-type signal lines include at least one kind of first-type signal lines, and the plurality of first-type connection lines includes at least one kind of first-type connection lines, each kind of first-type signal lines are electrically connected with one of kinds of first-type connection lines, a quantity of at least one kind of first-type connection lines is 2M, in the column direction, 2M first-type connection lines of a same kind are sequentially arranged along the column direction, and an i-th first-type connection line and an (M+i)-th first-type connection line are electrically connected with one of the first-type signal lines, wherein i is an integer greater than or equal to 1, less than or equal to M, and M is an integer greater than or equal to 1.

In some exemplary implementations, categories of the plurality of first-type signal lines at least include a first power supply line, categories of the plurality of first-type connection lines at least include a first power supply connection line, a quantity of the first power supply line is multiple, a quantity of the first power supply connection line is 2M, in the column direction, 2M first power supply connection lines are arranged sequentially, and an i-th first power supply connection line and an (M+i)-th first power supply connection line are electrically connected to one of the first power supply lines.

In some exemplary implementations, in the row direction, at least one of the first power supply connection lines is located between two adjacent rows of element groups; in the column direction, at least one of the first power supply lines is located between two adjacent columns of element groups.

In some exemplary implementations, the plurality of element groups form 2M rows and each first power supply connection line is configured to be electrically connected with a row of element groups adjacent thereto.

In some exemplary implementations, the display substrate further includes a plurality of second-type signal lines and a plurality of third-type signal lines; on the plane parallel to the display substrate, the plurality of second-type signal lines and the plurality of third-type signal lines all extend along the column direction and are arranged at intervals along the row direction; the plurality of element groups form 2M rows, in one column of element groups, a first row of element groups to an M-th row of element groups are electrically connected to the second-type signal lines, and an (M+1)-th row of element groups to a 2M-th row of element groups are electrically connected to the third-type signal lines.

In some exemplary implementations, the display substrate further includes at least one drive circuit, the display substrate includes a display region, the plurality of element groups are disposed in the display region, in a direction parallel to the plane where the display substrate is located, the drive circuit is disposed at a side of the display region, one end of a first-type signal line, one end of a second-type signal line, and one end of a third-type signal line are electrically connected with a corresponding drive circuit, and the other end of the first-type signal line, the other end of the second-type signal line, and the other end of the third-type signal line extend to the display region.

In some exemplary implementations, the second-type signal lines include a plurality of first data signal lines, the third-type signal lines include a plurality of second data signal lines, the first data signal lines go through the display region in the column direction, and the second data signal lines extend from the 2M-th row of element groups to the (M+1)-th row of element groups in the display region.

In some exemplary implementations, the display substrate further includes a plurality of common potential signal lines and a plurality of fixed potential signal lines electrically connected with a plurality of columns of element groups, respectively, the plurality of first-type signal lines include a plurality of first power supply lines, on the plane parallel to the display substrate, the plurality of common potential signal lines and the plurality of fixed potential signal lines all extend along the column direction and are arranged at intervals along the row direction, in the row direction, among signal lines electrically connected with one of columns of element groups, a fixed potential signal line and a first power supply line respectively are located at two sides of a common potential signal line, and an orthographic projection of the common potential signal line on the base substrate is at least partially overlapped with an orthographic projection of the column of element groups on the base substrate.

In some exemplary implementations, an element group includes a first-type light emitting element and a second-type light emitting element, a fixed potential signal line includes a first fixed potential signal line and a second fixed potential signal line, the first fixed potential signal line is electrically connected to the first-type light emitting element and the second fixed potential signal line is electrically connected to the second-type light emitting element.

In some exemplary implementations, in the row direction, a size of the common potential signal line is larger than a size of the first fixed potential signal line and a size of the first-type signal line, and a size of the second fixed potential signal line is smaller than the size of the first fixed potential signal line and the size of the first-type signal line.

In some exemplary implementations, in the row direction, the size of the common potential signal line is 1.5 to 3 times the size of the second fixed potential signal line.

In some exemplary implementations, the element group further includes a control circuit, and the control circuit is electrically connected to the first-type light emitting element, the second-type light emitting element, the first power supply line and the common potential signal line, and is electrically connected to one of the first data signal line and the second data signal line, among signal lines electrically connected with one of columns of element groups, in the row direction, the common potential signal line is located at a side of the control circuit, and the first data signal line and the second data signal line are located at the other side of the control circuit.

In some exemplary implementations, in the row direction, among signal lines electrically connected with one of columns of element groups, the first data signal line and the second data signal line are located between the common potential signal line and the first power supply line.

In some exemplary implementations, in the row direction, among signal lines electrically connected with one of columns of element groups, a first distance between the common potential signal line and the first data signal line is greater than a second distance between the common potential signal line and the second fixed potential signal line.

In some exemplary implementations, the first data signal line, the first power supply line, the first fixed potential signal line, and the second fixed potential signal line are sequentially arranged between adjacent two common potential signal lines in the row direction, and a distance between adjacent two signal lines is consistent with the second distance.

In a second aspect, an embodiment of the present disclosure provides a display apparatus, including at least one display substrate according to any one of the embodiments described above.

Other aspects may be comprehended after the drawings and the detailed descriptions are read and understood.

### BRIEF DESCRIPTION OF DRAWINGS

Accompanying drawings are used for providing further understanding of technical solutions of the present disclosure, constitute a portion of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, and are only intended to schematically describe contents of the present disclosure.

FIG. 1 is a schematic diagram of a display substrate according to at least one embodiment of the present disclosure.

FIG. 2 shows a schematic diagram of a display substrate according to an exemplary embodiment of the present disclosure.

FIG. 3 is an enlarged schematic view of the position M1 in FIG. 1.

FIG. 4 is an enlarged schematic view of the position M1 in FIG. 1.

FIG. 5 is an enlarged schematic view of the position M2 of FIG. 3.

FIG. 6 is a schematic diagram of a cross-section structure of the B-B position in FIG. 5.

FIG. 7 is a schematic diagram of a display apparatus according to at least one embodiment of the present disclosure.

FIG. 8 is a schematic diagram of a display apparatus according to at least one embodiment of the present disclosure.

### DETAILED DESCRIPTION

The embodiments of the present disclosure will be described below with reference to the drawings in detail. Implementation modes may be implemented in a plurality of different forms. Those of ordinary skills in the art may easily understand such a fact that implementations and contents may be transformed into one or more forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, an implementation of the present disclosure is not always limited to the size, and the shape and size of each component in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limits in numbers but only to avoid confusion between composition elements. In the present disclosure, “multiple” may include two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements with reference to the accompanying drawings, not to indicate or imply that involved devices or elements are required to have specific orientations and be structured and operated with the specific orientations but only to easily and simply describe the present specification, and thus should not be understood as limitations on the present disclosure. The positional relationships between the constituent elements are changed as appropriate based on directions according to which the constituent elements are described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be fixed connection, or a detachable connection, or an integral connection; it may be a mechanical connection or an electrical connection; it may be a direct connection, or an indirect connection through middleware, or internal communication inside two elements. Those of ordinary skills in the art may understand meanings of the aforementioned terms in the present disclosure according to situations.

In the specification, “electrical connection” includes connection of composition elements through an element with a certain electrical action. An “element with a certain electrical action” is not particularly limited as long as electrical signals between the connected constituent elements may be sent and received. Examples of the “element with the certain electrical effect” not only include electrodes and wirings, but also include switching elements such as transistors, resistors, inductors, capacitors, other elements with one or more functions, etc.

In the specification, a transistor refers to an element that at least includes three terminals, i.e., a gate electrode, a drain electrode, and a source electrode. The transistor has a channel region between the drain electrode (drain electrode terminal, drain area, or drain) and the source electrode (source electrode terminal, source area, or source), and a current can flow through the drain electrode, the channel region and the source electrode. In the present disclosure, the channel region refers to a region through which a current mainly flows.

In this specification, for distinguishing the two electrodes except the gate electrode of the transistor, one electrode is called a first electrode, and the other electrode is called a second electrode. The first electrode may be the source electrode or the drain electrode, and the second electrode may be the drain electrode or the source electrode. In addition, a gate electrode of a transistor may be called a control electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, and deformation, etc.

In the specification, a “film” and a “layer” are interchangeable. For example, a “conductive layer” may be replaced with a “conductive film” sometimes. Similarly, an “insulating film” may be replaced with an “insulating layer” sometimes.

In the specification, “about” and “substantially” refer to that a boundary is not defined strictly and a case within a process and measurement error range is allowed. In this specification, “substantially the same” may be a case where numerical values differ by less than 10%.

In the present disclosure, “thickness” and “height” refer to a vertical distance between a surface of a side of a film layer away from the base substrate and a surface of a side close to the base substrate.

During the display process of LCD, the emitted light from the backlight source will pass through the polarizer and color filter in turn, and there is a lot of energy loss during the display process; whereas Mini/Micro LED display adopts a three primary colors sub-pixel self-illuminating structure, the power consumption of Mini/Micro LED can be reduced by about 10%. Compared to the LCD display Mini/Micro LED uses inorganic materials to emit light, which has higher luminous efficiency, while OLED uses organic materials to emit light. With the comparison of the two, Mini/Micro LED emits light with lower power consumption than OLED. Moreover, unlike OLED which uses organic material, Mini/Micro LEDs uses Gallium Nitride (GaN) material in the light emitting part, which can provide a significantly better brightness than that of OLED. In Mini/Micro LED display products, each Mini/Micro LED is a pixel capable of self-illumination, and at the same time a single Mini/Micro LED is at the micron level, so it can achieve very high resolution. In related technologies, the pixel density of Mini/Micro LED displays can reach more than 1500 PPI, while the PPI of LCD and OLED screens is about 800 PPI and 400 PPI.

Based on the above advantages, Mini/Micro LED displays will become the next generation of displays after LCD displays and OLED displays, with broad application prospects.

Micro Light Emitting Diode (Micro-LED) and Mini Light Emitting Diode (Mini-LED) are mainly made by miniaturizing, arraying, and thin-filming traditional light emitting diodes with microprocessing technology, and then transferring the light emitting diode thin film to the drive backplane in batches by giant transfer technology. Mini Diode (Mini-LED) and Micro Light Emitting Diode (Micro-LED) has the characteristics of high brightness and small light emitting area, which has obvious advantages in the field of transparent display. Transparent display is widely used in display windows, transparent televisions, vehicles, VR glasses and other fields.

At present, for large-size transparent display products on the market, due to the increase in the size of the display panel, the quantity of pixels passed by a signal of each signal line increases, and there are problems of large power consumption and uneven display; in addition, as the pitch between pixels of the display product (that is, the shortest distance between two adjacent pixels) decreases, the quantity of output lines of the display product increases accordingly, resulting in a low overall transmittance of the transparent display product. Therefore, how to improve the transmittance and display uniformity of transparent displays is a problem that needs to be solved urgently.

The present embodiment provides a display substrate, which may include: a base substrate and a plurality of element groups, a plurality of first-type signal lines and a plurality of first-type connection lines provided on the base substrate; on a plane parallel to the display substrate, the plurality of element groups are arranged in an array; the plurality of first-type signal lines extend along a column direction and are arranged at intervals in a row direction; the plurality of first-type connection lines extend along the row direction and are arranged at intervals along the column direction, and the row direction intersects the column direction; in a direction perpendicular to a plane where the display substrate is located, a first-type signal line and a first-type connection line are located in different conductive layers;

A first-type signal line is electrically connected to at least two non-adjacent first-type connection lines, and a first-type connection line is electrically connected to at least some of element groups in one of rows of element groups.

In the display substrate according to an embodiment of the present disclosure, a first-type signal line is electrically connected to at least two non-adjacent first-type connection lines, which can reduce the quantity of the first-type signal lines, and thus can improve the transmittance of the display substrate.

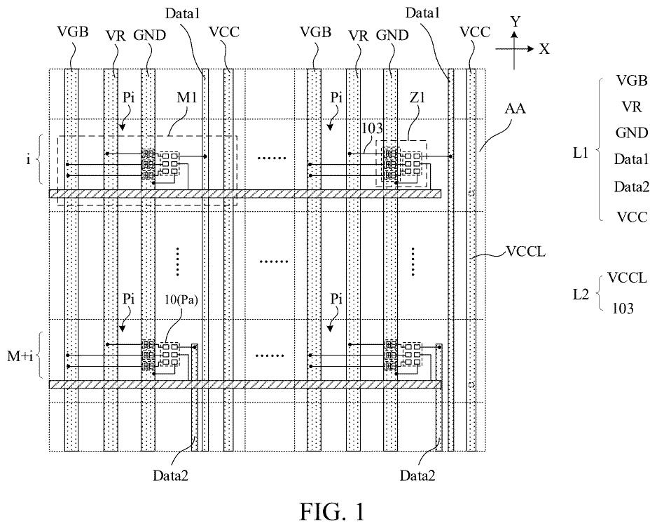

As shown in FIG. 1, the display substrate according to an embodiment of the present disclosure may include: a base substrate, a plurality of element groups Z1, a plurality of first-type signal lines and a plurality of first-type connection lines provided on the base substrate. In a direction parallel to a plane where the display substrate is located, the plurality of element groups Z1 are arranged in an array, the plurality of first-type signal lines extend along a column direction Y and are arranged at intervals along a row direction X, and the plurality of first-type connection lines extend along the row direction X and are arranged at intervals in along column direction Y, the row direction X intersects the column direction Y; in a direction perpendicular to the plane where the display substrate is located, a first-type signal line and a first-type connection line are located in different conductive layers;

A first-type signal line is electrically connected to at least two non-adjacent first-type connection lines, and a first-type connection line is electrically connected to at least some of element groups Z1 in one of rows of element groups.

In an exemplary implementation, as shown in FIG. 1, the plurality of first-type signal lines include at least one kind of first-type signal lines, and the plurality of first-type connection lines includes at least one kind of first-type connection lines, each kind of first-type signal lines are electrically connected to one of kinds of first-type connection lines, a quantity of at least one kind of first-type connection lines is 2M, in the column direction, 2M first-type connection lines of a same kind are sequentially arranged along the column direction Y, and an i-th first-type connection line and an (M+i)-th first-type connection line are electrically connected to one of the first-type signal lines, wherein i is an integer greater than or equal to 1, less than or equal to M, and M is an integer greater than or equal to 1.

In an exemplary implementation, as shown in FIG. 1, categories of the plurality of first-type signal lines includes at least a first power supply line VCC, categories of the plurality of first-type connection lines includes at least a first power supply connection line VCC1, a quantity of the first power supply line VCC is multiple, a quantity of the first power supply connection line VCCL may be 2M, in the column direction Y, the 2M first power supply connection lines VCCL are arranged sequentially, and an i-th power supply connection line and an (M+i)-th first power supply connection line VCCL are electrically connected to one of the first power supply lines VCC.

In an exemplary implementation, the i-th first power supply connection line and the (M+i)-th first power supply connection line VCCL are electrically connected to one of the first power supply lines VCC, that is, one first power supply line VCC can provide a first power supply signal for a row of element groups of an upper half screen and a row of element groups of a lower half screen in the display substrate. On the premise of improving display uniformity, the quantity of first-type signal lines can be reduced, so that the transmittance of the display substrate can be improved.

In an exemplary implementation, in the row direction X, at least one first power supply connection line VCCL is located between two adjacent rows of element groups; in the column direction Y, at least one first power supply line VCC is located between two adjacent columns of element groups. The first power supply connection line VCCL is disposed between two adjacent rows of element groups, and the first power supply line VCC is located between two adjacent columns of element groups, which can avoid as much as possible the shield to element group Z1, so that the transmittance of the display substrate can be improved.

In an exemplary implementation, the plurality of element groups Z1 form 2M rows, and each first power supply connection line VCCL is configured to be electrically connected with a row of element groups adjacent thereto, which can reduce the length of the connection wiring between the first power supply connection line VCCL and the element group Z1, minimize the voltage drop, and save space.

In an exemplary implementation, the display substrate may further include a plurality of second-type signal lines and a plurality of third-type signal lines; on a plane parallel to the display substrate, the plurality of second-type signal lines and the plurality of third-type signal lines all extend along the column direction Y and are arranged at intervals along the row direction X; the plurality of element groups Z1 form 2M, and in one column of element groups, a first row of element groups to an M-th row of element groups are electrically connected to a second-type signal line, and an (M+1)-th row of element groups to a 2M-th row of element groups are electrically connected to a third-type signal line, that is, the second-type signal line provides a signal to an upper half screen of the display substrate, and the third-type signal line provides a signal to a lower half screen of the display substrate, so that the display uniformity of the display substrate can be improved.

In an exemplary implementation, the second-type signal lines may include a plurality of first data signal lines Data1, and the third-type signal lines include a plurality of second data signal lines Data2. In a column of element groups Z1, a first row to an M-th row of element groups Z1 are electrically connected to a first data signal line Data1, and an (M+1)-th row to a 2M-th row of element groups are electrically connected to a second data signal line Data2.

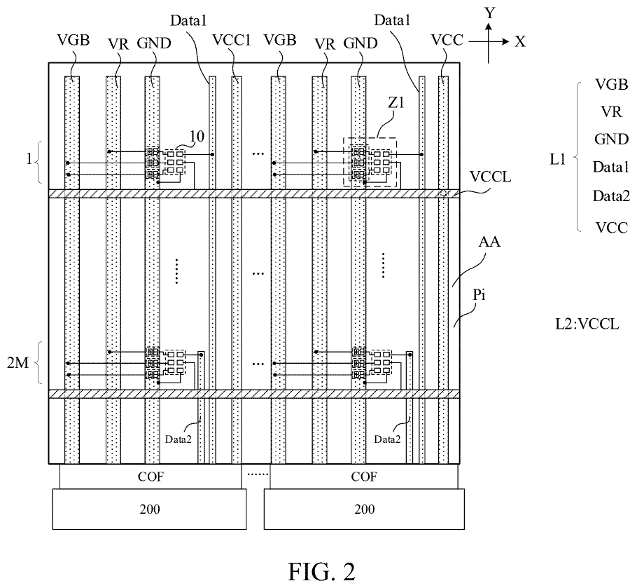

In an exemplary implementation, the display substrate may also include at least one drive circuit, the display substrate may include a display region, a plurality of element groups Z1 are provided in the display region, the drive circuit is provided at a side of the display region in a direction parallel to the plane where the display substrate is located, one end of a first-type signal line, one end of a second-type signal line, and one end of a third-type signal line are electrically connected to a corresponding drive circuit, and the other end of the first-type signal line, the other end of the second-type signal line, and the other end of the third-type signal line extend to the display region AA. In an exemplary implementation, as shown in FIG. 2, the drive circuit 200 is provided at a side of the display region AA in a direction parallel to the plane where the display substrate is located, one end of the first power supply line VCC, one end of the first data signal line Data1, and one end of the second data signal line Data2 are electrically connected to a corresponding drive circuit 200, and the other end of the first power supply line VCC, the other end of the first data signal line Data1, and the other end of the second data signal line Data2 extend to the display region AA.

In an exemplary implementation, as shown in FIGS. 1 and 2, since the display substrate generally forms a bonding region at an edge of at least one side in the column direction Y, the drive circuit 200 may be provided in the bonding region.

In an exemplary implementation, the drive circuit 200 may be electrically connected to signal traces in the display substrate using flip chip technology (e.g., Chip on film, COF). The COF device receives a Serial Peripheral Interface (SPI) communication signal from the drive circuit 200, converts the SPI signal into a data signal and a first power supply signal, and transmits the data signal to the first data signal line Data1 and the second data signal line Data2, transmits the first power supply signal to the first power supply line VCC, and transmits the first power supply signal to corresponding element groups by the first power supply line VCC and the first power supply connection line VCCL electrically connected thereto. In an exemplary implementation, the display substrate can be partitioned and driven by a plurality of drive circuits 200 so that a large-size display substrate can be realized.

In an exemplary implementation, in the column direction Y, the first data signal line Data1 goes through the display region AA, and the second data signal line Data2 extends from the 2M-th row of element groups Z1 to the (M+1)-th row of element groups Z1 in the display region AA, so that the first data signal line Data1 can be electrically connected with the first row of element groups to the M-th row of element groups of one of the columns in the display region AA, and the second data signal line Data2 can be electrically connected with the (M+1)-th row of element groups Z1 to the 2M-th row of element groups Z1 in the display region AA. In addition, the second data signal line Data2 does not have to extend to the first row to the M-th row, so that the transmittance of the display substrate can be increased while the display uniformity of the display substrate can be increased.

In an exemplary implementation, as shown in FIGS. 1 and 2, the display substrate may further include a plurality of common potential signal lines GND and a plurality of fixed potential signal lines electrically connected to a plurality of columns of element groups Z1, respectively, and the plurality of common potential signal lines GND and the plurality of fixed potential signal lines all extend along the column direction Y and are arranged at intervals along the row direction X. In the row direction X, among signal lines electrically connected to one of columns of element groups Z1, the fixed potential signal line and the first power supply line VCC are respectively located at two side of the common potential signal line GND, and an orthographic projection of the common potential signal lines GND on the base substrate is at least partially overlapped with an orthographic projection of a corresponding column of element groups Z1 on the base substrate.

In an exemplary implementation, the base substrate may be a transparent substrate that allows visible light to pass through, and in some embodiments, the transparent substrate may be of a material such as glass, quartz, plastic, polyimide, and the like.

In an exemplary implementation, the above-described display substrate provided in the present disclosure can be applied to the field of transparent display, such as smart transportation, smart window, and outdoor display. In FIG. 1, a plurality of pixel regions Pi are separated by dashed lines, and within one pixel region Pi, traces (e.g., the first fixed potential signal line VGB, the second fixed potential signal line VR, the common potential signal line GND, the first data signal line Data1, the second data signal line Data2, the first power supply line VCC, and the first power supply connection line VCCL), the connection line 103, the connection electrode region 102, and the pad region Pa are light-opaque regions, and the rest are light-transmissive regions. The ratio of the area of the light-opaque regions to the light-transmissive regions is in the range of 25:75 to 35:65 (e.g., 30:70).

In an exemplary implementation, in the row direction X, the fixed potential signal line may be located between two adjacent columns of element groups Z1, and the first data signal line Data1 and the second data signal line Data2 electrically connected to one of the columns of element groups Z1 are located between the common potential signal line GND and the first power supply line VCC electrically connected to that column of element groups Z1, so that the shield to the element groups can be avoided, and the transmittance of the display substrate can be improved.

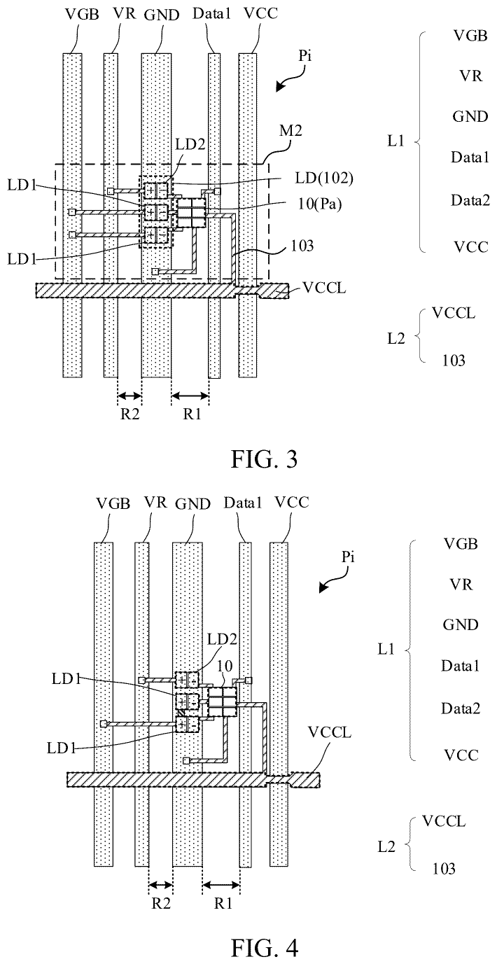

In an exemplary implementation, as shown in FIG. 3, which is an enlarged schematic view of the position M1 in FIG. 1, the element group Z1 may include a light emitting element LD, the light emitting element LD may include a first-type light emitting element LD1 and a second-type light emitting element LD2, and the fixed potential signal line includes a first fixed potential signal line VGB and a second fixed potential signal line VR, the first fixed potential signal line VGB is electrically connected to the first-type light emitting element LD1 and the second fixed potential signal line VR is electrically connected to the second-type light emitting element LD2.

In an exemplary implementation, in the row direction X, the size of the common potential signal line GND is larger than the size of the first fixed potential signal line VGB and the size of the first-type signal line, and the size of the second fixed potential signal line VR is smaller than the size of the first fixed potential signal line VGB and the size of the first-type signal line, so that the space occupied by the second fixed potential signal line can be reduced.

In an exemplary implementation, a plurality of common potential signal lines GND may be electrically connected to a plurality of element groups Z1 in a plurality of columns of element groups, respectively, a plurality of first fixed potential signal lines VGB may be electrically connected to the plurality of element groups Z1 in the plurality of columns of element groups, respectively, and a plurality of second fixed potential signal lines VR may be electrically connected to the plurality of element groups Z1 in the plurality of columns of element groups, respectively; alternatively, the common potential signal line GND, the first fixed potential signal line VGB, and the second fixed potential signal line VR may be first-type signal lines, that is, one signal line may provide signals for a row of element groups of an upper half screen and a row of element groups of an lower half screen in the display substrate, and the quantity of the first-type signal lines may be reduced on the premise of improving display uniformity, thereby improving the transmittance of the display substrate; alternatively, the common potential signal line GND, the first fixed potential signal line VGB, and the second fixed potential signal line VR may be second-type signal lines or third-type signal lines, that is, the second-type signal line provides a signal to the upper half screen of the display substrate, and the third-type signal line provides a signal to the lower half screen of the display substrate. In the case of improving the display uniformity of the display substrate, the transmittance of the display substrate can be improved, which is not limited in the present disclosure.

In an exemplary implementation, as shown in FIGS. 1 to 3, in the row direction X, the size of the common potential signal line GND is larger than the size of the first fixed potential signal line VGB and the size of the first power supply line VCC, and the size of the second fixed potential signal line VR is smaller than the size of the first fixed potential signal line VGB and the size of the first power supply line VCC.

In an exemplary implementation, in the row direction X, the size of the common potential signal line GND may be 1.5 to 3 times the size of the second fixed potential signal line VR. The large size of the common potential signal line GND along the line direction X reduces the voltage drop, which can improve the display uniformity of the display substrate.

In an exemplary implementation, the light emitting component Z1 may include a control circuit which may be used to control the first-type light emitting element LD1 and the second-type light emitting element LD2. In an exemplary implementation, the control circuit may be a miniature drive chip or may be a drive circuit consisting of at least two thin film transistors and capacitors.

In an exemplary implementation, the control circuit may be electrically connected to the first-type light emitting element LD1, the second-type light emitting element LD2, the first power supply line VCC, and the common potential signal line GND, and connected to one of the first data signal line Data1 and the second data signal line Data2. Among signal lines electrically connected to one of columns of element groups Z1, in the row direction X, the common potential signal line GND may be located at a side of the control circuit, and the first data signal line Data1 and the second data signal line Data2 may be located at the other side of the control circuit.

In an exemplary implementation, as shown in FIG. 3, the control circuit in the element group Z1 may be a miniature drive chip 10, which may be electrically connected to the first-type light emitting element LD1, the second-type light emitting element LD2, the first power supply line VCC and the common potential signal line GND, and the miniature drive chip 10 may also be electrically connected to one of the first data signal line Data1 and the second data signal line Data2. Among the signal lines electrically connected to one of columns of element groups, in the row direction X, the common potential signal line GND may be located at a side of the miniature drive chip 10, and the first data signal line Data1 and the second data signal line Data2 may be located at the other side of the miniature drive chip 10.

In an exemplary implementation, as shown in FIGS. 1 to 3, in the row direction X, among the signal lines electrically connected to one of columns of element groups, the first data signal line Data1 and the second data signal line Data2 may be located between the common potential signal line GND and the first power supply line VCC.

In an exemplary implementation, as shown in FIG. 3, in the row direction X, among the signal lines electrically connected to one of columns of element groups, the first distance R1 between the common potential signal line GND and the first data signal line Data1 is greater than the second distance R2 between the common potential signal line GND and the second fixed potential signal line VR, so that the miniature drive chip 10 can be accommodated between the common potential signal line GND and the first data signal line Data1.

In an exemplary implementation, in the row direction X, the first data signal line Data1, the first power supply line VCC, the first fixed potential signal line VGB, and the second fixed potential signal line VR are sequentially arranged between two adjacent common potential signal lines GND, and the distance between two adjacent signal lines is consistent with the second distance R2. The distance between the two adjacent signal lines is consistent with the second distance R2, so that the distribution of the signal lines can be uniform, thereby improving the display uniformity.

In an exemplary implementation, as shown in FIGS. 1 to 3, in order to achieve a color display, the first-type light emitting element LD1 and the second-type light emitting element LD2 are configured to emit light in of different wavelength bands, respectively, wherein the second-type light emitting element LD2 emits light of a wavelength band of 615 nm to 650 nm, and the first-type light emitting element LD1 emits light of a wavelength band of 440 nm to 550 nm. For example, the second-type light emitting element LD2 includes only one kind of light emitting element, which is used to emit red light from 615 nm to 650 nm, and its peak wavelength thereof may be 600 nm. The first-type light emitting element LD1 includes two kinds of light emitting elements, which are used to emit blue light from 440 nm to 480 nm and green light from 495 nm to 550 nm, respectively, and the peak wavelengths thereof may be 450 nm and 530 nm, respectively.

In an exemplary implementation, the first-type light emitting element LD1 and the second-type light emitting element LD2 may both be inorganic light emitting diodes (LED). The category of inorganic light emitting diodes is not limited. LEDs having a quantum well junction, LEDs having a columnar structure, LEDs having a double heterojunction, etc. may be used. The LED may have a structures with a size miniaturized to the order of one hundred microns, that is, Mini LED or Micro LED, etc. The area of the light emitting region of the LED may be 1 mm² or less, or may be 10000 μm² or less, or may be 3000 μm² or less, or may be 700 μm² or less, or may be 200 μm² or less.

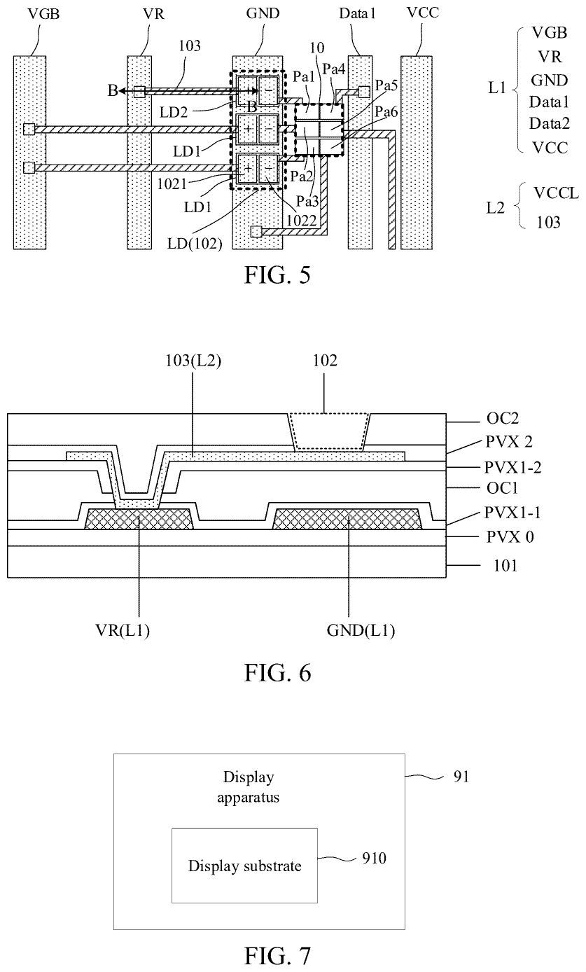

In an exemplary implementation, as shown in FIGS. 3 and 5, FIG. 5 is an enlarged schematic view of the position M2 in FIG. 3, the first-type light emitting element LD1 and the second-type light emitting element LD2 in the element group Z1 each include a first electrode “+” and a second electrode “−”, wherein the first electrode “+” of the first-type light emitting element LD1 is connected to a corresponding first fixed potential signal line VR through the connection line 103, the first electrode “+” of the second-type light emitting element LD2 is connected to a corresponding first fixed potential signal line VGB through the connection line 103, and the second electrodes “−” of the first-type light emitting element LD1 and the second-type light emitting element LD2 both are connected to the miniature drive chip 10 through the connection line 103, and the miniature drive chip 10 is also electrically connected to the common potential signal line GND, a data signal line (the first data signal line Data1 or the second data signal line Data2) and the first power supply line VCC through the connection line 103, respectively.

In an exemplary implementation, as shown in FIGS. 3 to 5, FIGS. 3 and 4 are schematic diagrams of a structure of a pixel region Pi, and FIG. 5 is an enlarged schematic diagram of a structure of the position M2 in FIG. 3, the miniature drive chip 10 may be bound and connected to the pad region Pa, which may be electrically connected to the corresponding signal trace or light emitting element through the connection line 103, thereby enabling the miniature drive chip 10 to realize electrical connection with the corresponding signal trace and light emitting element, for example, as shown in FIG. 5, the pad region Pa may include a first pad region Pa1, a second pad region Pa2, a third pad region Pa3, a fourth pad region Pa4, a fifth pad region Pa5, and a sixth pad region Pa6, In a same pixel region Pi, the first pad region Pa1 may be electrically connected to the second electrode “−” of the second-type light emitting element LD2 through the connection line 103, the second pad region Pa2 may be electrically connected to the second electrode “−” of one of the first-type light emitting elements LD1 through the connection line 103, the third pad region Pa3 may be electrically connected to the second electrode “−” of another first-type light emitting element LD1 through the connection line 103, the fourth pad region Pa4 may be electrically connected to the first data signal line Data1 or the second data signal line Data through the connection line 103, the fifth pad region Pa5 may be electrically connected to the first power supply connection line VCCL through the connection line 103 (refer to FIGS. 3 and 4), and the sixth pad region Pa6 may be electrically connected to the common potential signal line GND through the connection line 103.

In an exemplary implementation, as shown in FIG. 5, the electrode connection region 102 of each light emitting element LD may include a first electrode “+” connection region 1021 and a second electrode “−” connection region 1022, the first electrode “+” connection region 1021 may be connected to the first electrode “+” of the corresponding light emitting element LD and a corresponding trace (e.g., the first fixed potential signal line VGB or the second fixed potential signal line VR), and the second electrode “−” connection region 1022 may be connected to the second electrode “−” of the corresponding light emitting element LD and a corresponding pad region (e.g., one of the first pad regions Pa1 to the third pad regions Pa3).

In an exemplary implementation, the first power supply line VCC may transmit a DC signal as well as a digital signal, and the first power supply line VCC is used to provide power to the connected miniature drive chip 10. The first data signal line Data1 and the second data signal line Data2 transmit digital signals, and the miniature drive chip 10 receives the digital signal transmitted by the first data signal line Data1 or the second data signal line Data2 to determine the light emitting time of each light emitting element in the drive element group Z1, thereby controlling the brightness of each light emitting element. The common potential signal line GND transmits a set potential signal for providing a constant potential. The first electrode “+” of the second-type light emitting element LD2 is connected to the second fixed potential signal line VR, and the second electrode “−” of the second-type light emitting element LD2 is connected to the common potential signal line GND through the miniature drive chip 10, the second fixed potential signal line VR is used to provide a second fixed potential. The miniature drive chip 10 can control the on and off between the second-type light emitting element LD2 and the common potential signal line GND, so as to control the light emitting time of the second-type light emitting element LD2 by controlling the on time of the second-type light emitting element LD2. Similarly, the first electrode “+” of the first-type light emitting element LD1 is connected to the first fixed potential signal line VGB, and the second electrode “−” of the first-type light emitting element LD1 is connected to the common potential signal line GND through the miniature drive chip 10, the first fixed potential signal line VGB is used to provide a first fixed potential, and the miniature drive chip 10 can control the on and off between the first-type light emitting element LD1 and the common potential signal line GND, thereby controlling the light emitting time of the first-type light emitting element LD1 by controlling the on time of the first-type light emitting element LD1. When the first-type light emitting element LD1 includes two light emitting elements, the first electrodes “+” of the two light emitting elements may be respectively connected to the first fixed potential line VGB as shown in FIG. 3, or the first electrodes “+” of the two light emitting elements may be connected and then connected to the first fixed potential line VGB as shown in FIG. 4; the second electrodes “−” of the two light emitting elements are connected to the micro-drive chip 10, respectively.

In some embodiments, as shown in FIG. 6, which is a cross-sectional view taken along line B-B in FIG. 5, the display substrate may include a first conductive layer L1 and a second conductive layer L2. In some embodiments, the first power supply connection line VCCL may be located in the first conductive layer L1, and the first power supply line VCC may be located in the second conductive layer L2, the two are electrically connected through a via going through an insulating layer (e.g., the first inorganic insulating layer PVX1-1, the first organic insulating layer OC1, and the second inorganic insulating layer PVX1-2 that are stacked).

In an exemplary implementation, as shown in FIGS. 1 to 6, the display substrate may include a first conductive layer L1 and a second conductive layer L2, and the first power supply line VCC, the first fixed potential signal line VGB, the second fixed potential signal line VR, the common potential signal line GND, the first data signal line Data1, and the second data signal line Data2 may be disposed on the first conductive layer L1; the first power supply connection line VCCL and the multi-type connection line 103 may be disposed on the second conductive layer L2, and these connection lines 103 may be used to connect, respectively, the first fixed potential signal line VGB with the first-type light emitting element LD1, the second fixed potential signal line VR with the second-type light emitting element LD2, the first-type light emitting element LD1 with the miniature drive chip 10, the second-type light emitting element LD2 with the miniature drive chip 10, the miniature drive chip 10 with the first data signal line Data1 or the second data signal line Data2, and the miniature drive chip 10 with the first power supply connection line VCCL. In an exemplary implementation, the connection line 103 for connecting the miniature drive chip 10 with the first power supply connection line VCCL is integrally provided with the first power supply connection line VCCL.

In an exemplary implementation, the quantity of columns of the element groups Z1 arranged along the row direction X and the quantity of rows of the element groups Z1 arranged along the column direction Y may be different. For example, when the quantity of columns of the element groups Z1 arranged along the row direction X is greater than the quantity of rows of the element groups Z1 arranged along the column direction Y, only the same quantity of first power supply lines VCC as the quantity of columns of the element groups Z1 needs to be provided, and the first power supply lines VCC are electrically connected to the corresponding first power supply connection lines VCCL through vias in the insulating layer, respectively. When the arrangement of the element groups Z1 changes, the via connection mode of the first power supply lines VCC and the first power supply connection lines VCCL can be adaptively adjusted, which is not limited in embodiments of the present disclosure.

In an exemplary implementation, the quantity of the first power supply lines VCC may be different from the quantity of the first power supply connection lines VCCL, for example, the quantity of the first power supply connection lines VCCL may be twice the quantity of the first power supply lines VCC. In an exemplary implementation, the quantity of rows of the element groups Z1 arranged along the column direction Y may be twice the quantity of columns of the element groups Z1 arranged along the row direction X.

In an exemplary implementation, as shown in FIG. 6, the display substrate may further include a buffer layer (PVX0) located between the first conductive layer L1 and the base substrate 101, and the buffer layer (PVX0) may be made of an insulating material such as silicon nitride, to counteract the deformation of the base substrate 101 that may result from the process of preparing signal lines in the first conductive layer L1. When signal lines are provided at two sides of the base substrate 101, the stresses between the corresponding signal lines cancel each other, do not cause deformation of the base substrate 101, and a buffer layer (PVX0) may not be provided.

In an exemplary implementation, as shown in FIG. 6, the display substrate may also include a protective layer (e.g., a third inorganic insulating layer PVX2 and a second organic insulating layer OC2 that are stacked) disposed on a side of the second conductive layer L2 away from the base substrate 101. The third inorganic insulating layer can be made of materials such as silicon nitride, and directly cover a surface of the second conductive layer L2 away from the base substrate 101, so as to ensure the insulating protection of the signal lines of the second conductive layer L2. In an exemplary implementation, the protective layer has a via that exposes the connection electrode region 102 and the pad region Pa bound to the miniature drive chip 10.

An embodiment of the present disclosure also provides a display apparatus including at least one display substrate according to any one of the embodiments described above, as shown in FIG. 7, which is a schematic diagram of the display apparatus according to at least one embodiment of the present disclosure. As shown in FIG. 4, the present embodiment provides a display apparatus 91 including a display substrate 910. The display substrate 910 may be a micro-LED display substrate or a mini-LED display substrate. The display apparatus 91 may be: a car window glass, a mall cabinet, an augmented reality (AR, Augmented Reality) device, a virtual reality (VR, Virtual Reality) device, and any other products or components with the transparent display function. However, the present embodiment is not limited thereto.

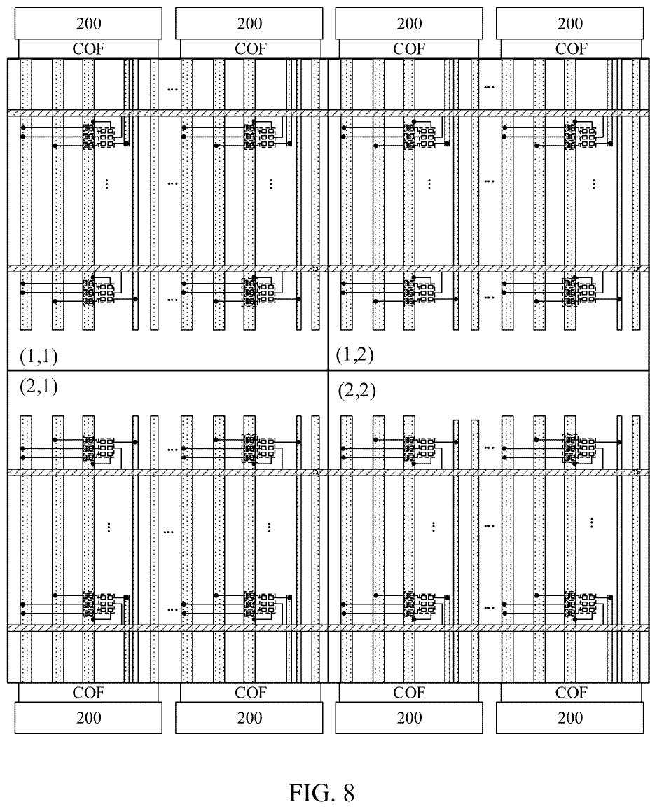

In an exemplary implementation, the display apparatus may be formed by splicing a plurality of display substrates to achieve a large screen display. As shown in FIG. 8, which shows a display apparatus is formed by splicing four display substrates. The four display substrates form two rows and two columns. The splicing exposure can be used between two adjacent columns and between two adjacent rows, so that the splicing gap is small or even visually invisible. In an exemplary implementation, in a display apparatus formed by splicing a plurality of display substrates, the drive circuit 200 may be located at two sides of the display apparatus in the column direction Y. As shown in FIG. 8, among the four display substrates in two rows and two columns in the display apparatus, (1, 1) is the display substrate in the first row and first column, (1, 2) is the display substrate in the first row and second column, (2, 1) is the display substrate in the first row and first column, and (2, 2) is the display substrate in the second row and second column.

In the display substrate and the display apparatus according to an embodiment of the present disclosure, a first-type signal line in the display substrate is electrically connected with at least two non-adjacent first-type connection lines, so that the quantity of the first-type signal lines can be reduced, and the transmittance of the display substrate can be improved.

The drawings of the present disclosure only involve structures involved in the present disclosure, and other structures may refer to conventional designs. The embodiments of the present disclosure and features in the embodiments may be combined to each other to obtain new embodiments if there is no conflict. Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A display substrate, comprising: a base substrate, a plurality of element groups, a plurality of first-type signal lines and a plurality of first-type connection lines disposed on the base substrate, wherein on a plane parallel to the display substrate, the plurality of element groups are arranged in an array, the plurality of first-type signal lines extend along a column direction and are arranged at intervals along a row direction, the plurality of first-type connection lines extend along the row direction and are arranged at intervals along the column direction, the row direction intersects the column direction; in a direction perpendicular to a plane where the display substrate is located, a first-type signal line and a first-type connection line are located in different conductive layers;
the first-type signal line is electrically connected to at least two non-adjacent first-type connection lines, and the first-type connection line is electrically connected to at least some of element groups in one of rows of element groups.

2. The display substrate according to claim 1, wherein the plurality of first-type signal lines comprises at least one kind of first-type signal lines, and the plurality of first-type connection lines comprises at least one kind of first-type connection lines, each kind of first-type signal lines are electrically connected with one of kinds of first-type connection lines, a quantity of at least one kind of first-type connection lines is 2M, in the column direction, 2M first-type connection lines of a same kind are sequentially arranged along the column direction, and an i-th first-type connection line and an (M+i)-th first-type connection line are electrically connected with one of the first-type signal lines, wherein i is an integer greater than or equal to 1, less than or equal to M, and M is an integer greater than or equal to 1.

3. The display substrate according to claim 2, wherein categories of the plurality of first-type signal lines at least comprise a first power supply line, categories of the plurality of first-type connection lines at least comprise a first power supply connection line, a quantity of the first power supply line is multiple, a quantity of the first power supply connection line is 2M, in the column direction, 2M first power supply connection lines are arranged sequentially, and an i-th first power supply connection line and an (M+i)-th first power supply connection line are electrically connected with one of the first power supply lines.

4. The display substrate according to claim 3, wherein in the row direction, at least one of the first power supply connection lines is located between two adjacent rows of element groups; in the column direction, at least one of the first power supply lines is located between two adjacent columns of element groups.

5. The display substrate according to claim 3, wherein the plurality of element groups form 2M rows, and each first power supply connection line is configured to be electrically connected with a row of element groups adjacent thereto.

6. The display substrate according to claim 1, further comprising a plurality of second-type signal lines and a plurality of third-type signal lines; on the plane parallel to the display substrate, the plurality of second-type signal lines and the plurality of third-type signal lines all extend along the column direction and are arranged at intervals along the row direction; the plurality of element groups form 2M rows, in one column of element groups, a first row of element groups to an M-th row of element groups are electrically connected to the second-type signal lines, and an (M+1)-th row of element groups to a 2M-th row of element groups are electrically connected to the third-type signal lines.

7. The display substrate according to claim 6, further comprising at least one drive circuit, wherein the display substrate comprises a display region, the plurality of element groups are disposed in the display region, in a direction parallel to the plane where the display substrate is located, the drive circuit is disposed at a side of the display region, one end of a first-type signal line, one end of a second-type signal line, and one end of a third-type signal line are electrically connected with a corresponding drive circuit, and the other end of the first-type signal line, the other end of the second-type signal line, and the other end of the third-type signal line extend to the display region.

8. The display substrate according to claim 6, wherein the second-type signal lines comprise a plurality of first data signal lines, the third-type signal lines comprise a plurality of second data signal lines, the first data signal lines go through the display region in the column direction, and the second data signal lines extend from the 2M-th row of element groups to the (M+1)-th row of element groups in the display region.

9. The display substrate according to claim 8, further comprising a plurality of common potential signal lines and a plurality of fixed potential signal lines electrically connected with a plurality of columns of element groups, respectively, wherein the plurality of first-type signal lines comprise a plurality of first power supply lines, on the plane parallel to the display substrate, the plurality of common potential signal lines and the plurality of fixed potential signal lines all extend along the column direction and are arranged at intervals along the row direction, in the row direction, among signal lines electrically connected with one of columns of element groups, a fixed potential signal line and a first power supply line respectively are located at two sides of a common potential signal line, and an orthographic projection of the common potential signal line on the base substrate is at least partially overlapped with an orthographic projection of the column of element groups on the base substrate.

10. The display substrate according to claim 9, wherein an element group comprises a first-type light emitting element and a second-type light emitting element, a fixed potential signal line comprises a first fixed potential signal line and a second fixed potential signal line, the first fixed potential signal line is electrically connected to the first-type light emitting element and the second fixed potential signal line is electrically connected to the second-type light emitting element.

11. The display substrate according to claim 10, wherein, in the row direction, a size of the common potential signal line is larger than a size of the first fixed potential signal line and a size of the first-type signal line, and a size of the second fixed potential signal line is smaller than the size of the first fixed potential signal line and the size of the first-type signal line.

12. The display substrate according to claim 11, wherein, in the row direction, the size of the common potential signal line is 1.5 to 3 times the size of the second fixed potential signal line.

13. The display substrate according to claim 10, wherein the element group further comprises a control circuit, and the control circuit is electrically connected to the first-type light emitting element, the second-type light emitting element, the first power supply line and the common potential signal line, and is electrically connected to one of the first data signal line and the second data signal line, among signal lines electrically connected with one of columns of element groups, in the row direction, the common potential signal line is located at a side of the control circuit, and the first data signal line and the second data signal line are located at the other side of the control circuit.

14. The display substrate according to claim 13, wherein, in the row direction, among signal lines electrically connected with one of columns of element groups, the first data signal line and the second data signal line are located between the common potential signal line and the first power supply line.

15. The display substrate according to claim 14, wherein, in the row direction, among signal lines electrically connected with one of columns of element groups, a first distance between the common potential signal line and the first data signal line is greater than a second distance between the common potential signal line and the second fixed potential signal line.

16. The display substrate according to claim 15, wherein the first data signal line, the first power supply line, the first fixed potential signal line, and the second fixed potential signal line are sequentially arranged between adjacent two common potential signal lines in the row direction, and a distance between adjacent two signal lines is consistent with the second distance.

17. A display apparatus, comprising at least one display substrate according to claim 1.

18. The display substrate according to claim 4, wherein the plurality of element groups form 2M rows, and each first power supply connection line is configured to be electrically connected with a row of element groups adjacent thereto.

19. The display substrate according to claim 1, further comprising a plurality of pixel regions, wherein a pixel region comprises a light-opaque region and a light-transmissive region, and a ratio of an area of the light-opaque region to an area of the light-transmissive region is in a range of 25:75 to 35:65.

20. The display substrate according to claim 3, further comprising a first conductive layer and a second conductive layer, wherein the first power supply connection line is located in the first conductive layer, the first power supply line is located in the second conductive layer, and the first power supply connection line and the first power supply line are electrically connected through a via going through an insulating layer.
